(19) United States
(12) Patent Application Publication
(10) Pub. No.: US 2025/0070809 A1
(43) Pub. Date: Feb. 27, 2025

(54) RADIO FREQUENCY MODULE

(71) Applicant: Murata Manufacturing Co., Ltd., Kyoto (JP)

(72) Inventor: Yoshihito OTSUBO, Kyoto (JP)

(21) Appl. No.: 18/945,956

(22) Filed: Nov. 13, 2024

Related U.S. Application Data
(63) Continuation of application No. PCT/JP2023/017874, filed on May 12, 2023.

(30) Foreign Application Priority Data
May 19, 2022 (JP) 2022-082644

(51) Int. Cl. H04B 1/16; H01Q 1/22; H04B 1/036; H04B 1/40

(52) U.S. Cl. CPC H04B 1/1607; H04B 1/036; H04B 1/40; H01Q 1/2283

(57) ABSTRACT

Provided is a radio frequency module which may not only reduce the height of the overall module but also ensure a sufficient degree of planarity as well. In a radio frequency module, a first electronic component is disposed on a wiring board. A second electronic component is built in the wiring board. A core board has a through hole. The first electronic component is arranged on a first buildup layer to overlap with the through hole of the core board when viewed in plan in a thickness direction defined for the core board. The second electronic component is disposed inside the through hole of the core board. Thickness of the second electronic component is greater than thickness of the core board when measured in the thickness direction defined for the core board. The second electronic component is electrically connected to the first electronic component via the first buildup layer.

### CROSS REFERENCE TO RELATED APPLICATION

This is a continuation of International Application No. PCT/JP2023/017874 filed on May 12, 2023 which claims priority from Japanese Patent Application No. 2022-082644 filed on May 19, 2022. The contents of these applications are incorporated herein by reference in their entireties.

### BACKGROUND OF THE DISCLOSURE

### Field of the Disclosure

The present disclosure generally relates to a radio frequency (RF) module and more particularly relates to an RF module including a core board and a plurality of buildup layers.

### Description of the Related Art

JP 5284155 B2 discloses a wiring board in which electronic components are built. In the wiring board of JP 5284155 B2, a through hole is provided through a core board and an electronic component is disposed inside the through hole of the core board. In addition, another electronic component is also disposed on the wiring board of JP 5284155 B2.

### BRIEF SUMMARY OF THE DISCLOSURE

There has been an increasing demand for not only further reducing the height of an RF module including a wiring board in which an electronic component is built but also ensuring a sufficient degree of planarity for such an RF module as well.

In view of the foregoing background, it is therefore a possible benefit of the present disclosure to provide an RF module which may not only reduce the height of the overall module but also ensure a sufficient degree of planarity as well.

A radio frequency module according to an aspect of the present disclosure includes a wiring board, a first electronic component, and a second electronic component. The first electronic component is disposed on the wiring board. The second electronic component is built in the wiring board. The wiring board includes a core board, a first buildup layer, and a second buildup layer. The core board has a first principal surface and a second principal surface facing each other. The first buildup layer is stacked on the first principal surface of the core board. The second buildup layer is stacked on the second principal surface of the core board. The core board has a through hole. The first electronic component is arranged on the first buildup layer to overlap with the through hole of the core board when viewed in plan in a thickness direction defined for the core board. The second electronic component is disposed inside the through hole of the core board. A thickness of the second electronic component is greater than a thickness of the core board when measured in the thickness direction defined for the core board. The second electronic component is electrically connected to the first electronic component via the first buildup layer.

The radio frequency module according to this aspect of the present disclosure may not only reduce the height of the overall module but also ensure a sufficient degree of planarity as well.

### BRIEF DESCRIPTION OF THE SEVERAL VIEWS OF THE DRAWINGS

FIG. 1 is a cross-sectional view of an RF module according to a first embodiment;

FIG. 2 is a cross-sectional view of a main part of the RF module;

FIG. 3 is a cross-sectional view of an RF module according to a second embodiment;

FIG. 4 is a transparent view of a main part of the RF module;

FIG. 5 is a cross-sectional view of an RF module according to a third embodiment;

FIG. 6 is a cross-sectional view of an RF module according to a fourth embodiment;

FIG. 7 is a cross-sectional view of an RF module according to a fifth embodiment;

FIG. 8 is a cross-sectional view of an RF module according to a variation of the fifth embodiment;

FIG. 9 is a cross-sectional view of an RF module according to a sixth embodiment;

FIG. 10 is a cross-sectional view of an RF module according to a seventh embodiment; and

FIG. 11 is a cross-sectional view of an RF module according to an eighth embodiment.

### DETAILED DESCRIPTION OF THE DISCLOSURE

The drawings to be referred to in the following description of first to eighth embodiments and their variations are all schematic representations. Thus, the ratio of the dimensions (including thicknesses) of respective constituent elements illustrated on the drawings does not always reflect their actual dimensional ratio.

### First Embodiment

### (1) Overview

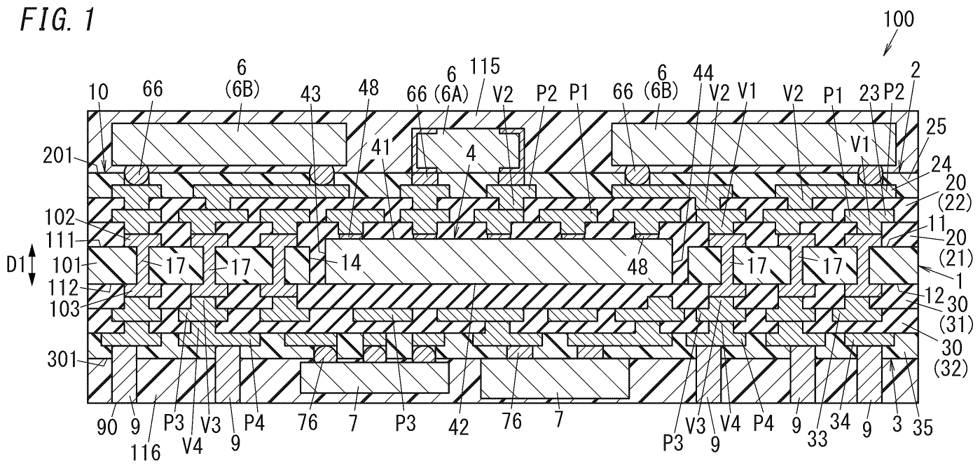

As shown in FIG. 1, an RF module 100 according to a first embodiment includes a wiring board 10, a plurality of electronic components 6, and an electronic component 4 (second electronic component). The plurality of electronic components 6 includes an electronic component 6A (first electronic component) and a plurality of electronic components 6B. The plurality of electronic components 6 are arranged on the wiring board 10. The electronic component 4 is built in the wiring board 10.

The wiring board 10 includes a core board 1, a first buildup layer 2, and a second buildup layer 3. The core board 1 has a first principal surface 11 and a second principal surface 12 facing each other. As used herein, the phrase “facing each other” refers to facing each other geometrically, not physically. The first buildup layer 2 is stacked on the first principal surface 11 of the core board 1. The second buildup layer 3 is stacked on the second principal surface 12 of the core board 1.

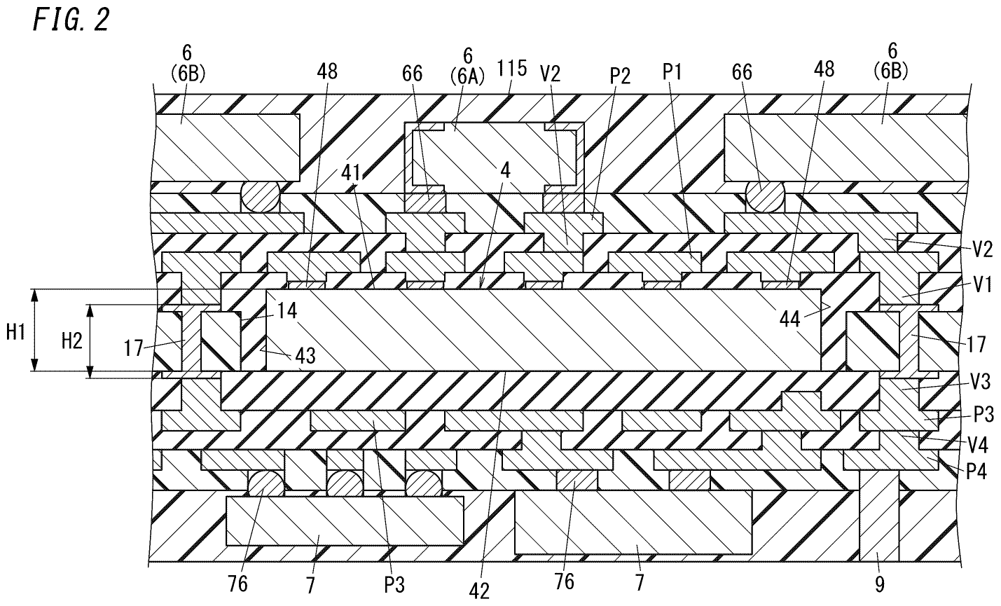

The core board 1 has a through hole 14. The through hole 14 is provided through a central area of the core board 1 when viewed in plan in the thickness direction D1 defined for the core board 1. The electronic component 6A is arranged on the first buildup layer 2 to overlap with the through hole 14 of the core board 1 when viewed in plan in the thickness direction D1 defined for the core board 1. The electronic component 4 is disposed in a region, covering the central area of the core board 1, inside the through hole 14 of the core board 1. The thickness H1 of the electronic component 4 is greater than the thickness H2 of the core board 1 (refer to FIG. 2) when measured in the thickness direction D1 defined for the core board 1. The electronic component 4 is electrically connected to the electronic component 6A via the first buildup layer 2.

The RF module 100 further includes a plurality of electronic components 7, a plurality of external connection terminals 9, a first resin layer 115 and a second resin layer 116. The plurality of electronic components 7 are arranged on the second buildup layer 3. The plurality of external connection terminals 9 are arranged on the second buildup layer 3. The first resin layer 115 is disposed on the first buildup layer 2 to cover the electronic components 6 partially. The second resin layer 116 is disposed on the second buildup layer 3 to cover each of the plurality of external connection terminals 9 and the electronic components 7 partially. The RF module 100 has a double-sided mounting structure in which the electronic components 6, 7 are mounted on both sides of the wiring board 10.

The RF module 100 may be used, for example, in a communications device. The communications device may be, without limitation, a cellphone (such as a smartphone), for example. Alternatively, the communications device may also be a wearable terminal (such as a smartwatch). The RF module 100 is a module compatible with, for example, a fourth-generation mobile communications (4G) standard or a fifth-generation mobile communications (5G) standard. Examples of the 4G standard include the third-generation partnership project (3GPP (R)) standard and the long-term evolution (LTE (R)) standard. Examples of the 5G standards include the 5G new radio (NR) standard. The RF module 100 is a module compatible with the carrier aggregation and dual connectivity, for example.

### (2) Details

Next, an RF module 100 according to a first embodiment will be described in further detail with reference to FIG. 1.

### (2.1) Core Board

As shown in FIG. 1, the core board 1 has a first principal surface 11 and a second principal surface 12. When viewed in plan in the thickness direction D1 defined for the core board 1, the outer edges of the core board 1 have a quadrangular shape, for example.

The core board 1 includes a dielectric substrate 101, a first conductive layer 102, a second conductive layer 103, and a plurality of feedthrough via conductors 17. In the core board 1, the first conductive layer 102 is disposed on one principal surface 111 of the dielectric substrate 101 and the second conductive layer 103 is disposed on the other principal surface 112 of the dielectric substrate 101. Each of the first conductive layer 102 and the second conductive layer 103 is formed to have one or more predetermined patterns which are defined on a layer-by-layer basis. The core board 1 may be, for example, a double-sided printed wiring board. Examples of materials for the dielectric substrate 101 include an epoxy resin, a polyimide resin, and a composite material of an epoxy resin and a glass fiber. A material for the first conductive layer 102 and the second conductive layer 103 may be copper, for example. A material for the feedthrough via conductors 17 may include copper, for example.

The first principal surface 11 and second principal surface 12 of the core board 1 face each other in the thickness direction D1 defined for the core board 1. Optionally, the first principal surface 11 and second principal surface 12 of the core board 1 may have microscopic unevenness or have only microscopic recesses or projections.

The core board 1 has a through hole 14. The through hole 14 is provided through the central area of the core board 1 when viewed in plan in the thickness direction D1 defined for the core board 1. The electronic component 4 is disposed inside the through hole 14 of the core board 1.

### (2.2) First Buildup Layer

The first buildup layer 2 is stacked on the first principal surface 11 of the core board 1 and a principal surface 41 of the electronic component 4. The first buildup layer 2 includes a plurality of (e.g., two) first dielectric layers 20. If the two first dielectric layers 20 need to be distinguished from each other, then the two first dielectric layers 20 will be hereinafter referred to as a first dielectric layer 21 and a first dielectric layer 22, respectively. In the first buildup layer 2, the first dielectric layer 21 is a first dielectric layer 20 located closest to the first principal surface 11 of the core board 1 in the thickness direction D1 defined for the core board 1. Also, in the first buildup layer 2, the first dielectric layer 22 is a first dielectric layer 20 located most distant from the first principal surface 11 of the core board 1 in the thickness direction D1 defined for the core board 1.

In addition, the first buildup layer 2 further includes a plurality of (e.g., two) first conductor layers 23, 24. The first conductor layer 23 is interposed between the first dielectric layers 21, 22. The first conductor layer 24 is formed on the first dielectric layer 22. These two first conductor layers 23, 24 are formed in one or more predetermined patterns which are defined on a layer-by-layer basis. The first conductor layer 23 includes one or more rewiring portions (conductor portions) P1 as the one or more predetermined patterns. The first conductor layer 24 includes one or more rewiring portions (conductor portions) P2 as the one or more predetermined patterns. In addition, the first buildup layer 2 further includes a plurality of via conductors V1 that connect the first conductor layer 23 and the first conductive layer 102 of the core board 1 to each other and a plurality of via conductors V2 that connect the first conductive layers 24, 23 to each other.

Examples of materials for the plurality of first dielectric layers 20 include an epoxy resin, a phenolic resin, a urethane resin, a silicone resin, and a polyimide resin. A material for the plurality of first conductor layers 23, 24 may include, for example, copper.

In addition, the first buildup layer 2 further includes a first resist layer 25. The first resist layer 25 is stacked on the first dielectric layer 22 and the first conductor layer 24. The first resist layer 25 is formed in a predetermined pattern and has a plurality of openings that expose respective parts of the plurality of rewiring portions P2. The first resist layer 25 may be, for example, a solder resist layer. A material for the first resist layer 25 may be a material having a lower degree of solder wettability than the first conductor layer 24. Examples of materials for the first resist layer 25 include a polyimide resin and an epoxy resin.

### (2.4) Second Buildup Layer

The second buildup layer 3 is stacked on the second principal surface 12 of the core board 1 and a principal surface 42 of the electronic component 4. The second buildup layer 3 includes a plurality of (e.g., two) second dielectric layers 30. If the two second dielectric layers 30 need to be distinguished from each other, then the two second dielectric layers 30 will be hereinafter referred to as a second dielectric layer 31 and a second dielectric layer 32, respectively. In the second buildup layer 3, the second dielectric layer 31 is a second dielectric layer 30 located closest to the second principal surface 12 of the core board 1 in the thickness direction D1 defined for the core board 1. Also, in the second buildup layer 3, the second dielectric layer 32 is a second dielectric layer 30 located most distant from the second principal surface 12 of the core board 1 in the thickness direction D1 defined for the core board 1.

In addition, the second buildup layer 3 further includes a plurality of (e.g., two) second conductor layers 33, 34. The second conductor layer 33 is interposed between the second dielectric layers 31, 32. The second conductor layer 34 is formed on the second dielectric layer 31. These two second conductor layers 33, 34 are formed in one or more predetermined patterns which are defined on a layer-by-layer basis. The second conductor layer 33 includes one or more rewiring portions (conductor portions) P3 as the one or more predetermined patterns. The second conductor layer 34 includes one or more rewiring portions (conductor portions) P4 as the one or more predetermined patterns. In addition, the second buildup layer 3 further includes a plurality of via conductors V3 that connect the second conductor layer 33 and the second conductive layer 103 of the core board 1 to each other and a plurality of via conductors V4 that connect the second conductor layers 34, 33 to each other.

Examples of materials for the plurality of second dielectric layers 30 include an epoxy resin, a phenolic resin, a urethane resin, a silicone resin, and a polyimide resin. A material for the plurality of second conductor layers 33, 34 may include, for example, copper.

In addition, the second buildup layer 3 further includes a second resist layer 35. The second resist layer 35 is stacked on the second dielectric layer 32 and the second conductor layer 34. The second resist layer 35 is formed in a predetermined pattern and has a plurality of openings that expose respective parts of the plurality of rewiring portions P4. The second resist layer 35 may be, for example, a solder resist layer. A material for the second resist layer 35 may be a material having a lower degree of solder wettability than the second conductor layer 34. Examples of materials for the second resist layer 35 include a polyimide resin and an epoxy resin.

### (2.4) Electronic Components 6

As shown in FIG. 1, the plurality of electronic components 6 are arranged on the wiring board 10. More specifically, the plurality of electronic components 6 are arranged on the first buildup layer 2. The electronic components 6 may be, for example, IC chips or surface mount electronic components. Examples of the IC chips include a power amplifier, a low-noise amplifier, a switch, and a controller. Examples of the surface mount electronic components include a chip inductor and a chip capacitor. Optionally, each of the electronic components 6 may also be, for example, a filter, a multiplexer, or a coupler. Examples of the filter include a surface acoustic wave filter, a bulk acoustic wave filter, and an LC filter. Alternatively, the electronic components 6 may also be electronic components each including a plurality of filters. As used herein, the expression “the electronic components 6 are arranged on the first buildup layer 2” refers to both a situation where the electronic components 6 are mounted on (i.e., mechanically connected to) the first buildup layer 2 and a situation where the electronic components 6 are electrically connected to (appropriate rewiring portions P2 of) the first buildup layer 2. The electronic components 6 are mounted on the second principal surface 201 of the first buildup layer 2 by bonding the electronic components 6 to the plurality of rewiring portions P2 of the first buildup layer 2 via a plurality of bonding portions 66, for example. A material for the plurality of bonding portions 66 may be solder, for example. The plurality of bonding portions 66 may be constituent elements of the electronic components 6 or constituent elements interposed between the electronic components 6 and the principal surface 201 of the first buildup layer 2, whichever is appropriate. If the plurality of bonding portions 66 are constituent elements of the electronic components 6, then the plurality of bonding portions 66 are conductive bumps.

In the example shown in FIG. 1, the electronic component 6A is a chip capacitor and the electronic component 6B is an IC chip.

The electronic component 6A is arranged on the first buildup layer 2 to overlap with the through hole 14 of the core board 1 when viewed in plan in the thickness direction D1 defined for the core board 1. As used herein, the expression “the electronic component 6A overlaps with the through hole 14 of the core board 1” refers to both a situation where part of the electronic component 6A overlaps with the through hole 14 of the core board 1 either partially or entirely and a situation where all of the electronic component 6A overlaps with the through hole 14 of the core board 1 either partially or entirely.

### (2.5) Electronic Components 7

The plurality of electronic components 7 are arranged on the wiring board 10. More specifically, the plurality of electronic components 7 are arranged on the second buildup layer 3. The electronic components 7 may be, for example, IC chips or surface mount electronic components. Examples of the IC chips include a power amplifier, a low-noise amplifier, a switch, and a controller. Examples of the surface mount electronic components include a chip inductor and a chip capacitor. The electronic components 7 may be, for example, filters, multiplexers, or couplers. The filter may be, for example, a surface acoustic wave filter, a bulk acoustic wave filter, or an LC filter. Optionally, each of the electronic components 7 may also be an electronic component including a plurality of filters. As used herein, the expression “the electronic components 7 are arranged on the second buildup layer 3” refers to both a situation where the electronic components 7 are mounted on (i.e., mechanically connected to) the second buildup layer 3 and a situation where the electronic components 7 are electrically connected to (appropriate rewiring portions P4 of) the second buildup layer 3. The electronic components 7 are mounted on the principal surface 301 of the second buildup layer 3 by bonding the electronic components 7 to the plurality of rewiring portions P4 of the second buildup layer 3 via a plurality of bonding portions 76, for example. A material for the plurality of bonding portions 76 may be solder, for example. The plurality of bonding portions 76 may be constituent elements of the electronic components 7 or constituent elements interposed between the electronic components 7 and the principal surface 301 of the second buildup layer 3, whichever is appropriate. If the plurality of bonding portions 76 are constituent elements of the electronic components 7, then the plurality of bonding portions 76 are conductive bumps.

### (2.6) Electronic Component 4

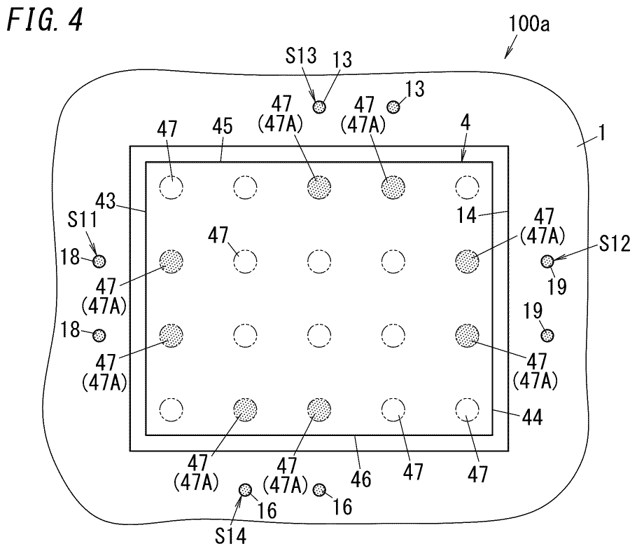

The electronic component 4 is built in the wiring board 10. More specifically, the electronic component 4 is disposed inside the through hole 14 of the core board 1. When viewed in plan in the thickness direction D1 defined for the core board 1, the outer edges of the electronic component 4 have a quadrangular shape, for example. The electronic component 4 has two principal surfaces 41, 42 facing each other in the thickness direction D1 defined for the core board 1. The electronic component 4 also has side surfaces 43-46 (refer to FIG. 4). A part of the first dielectric layer 20 of the first buildup layer 2 is located between the side surfaces 43-46 of the electronic component 4 and the inner peripheral surface of the through hole 14 of the core board 1.

The electronic component 4 may be, for example, an IC chip or a surface mount electronic component. Examples of the IC chip include a power amplifier, a low-noise amplifier, a switch, and a controller. Examples of the surface mount electronic component include a chip inductor and a chip capacitor. The electronic component 4 may be, for example, a filter, a multiplexer, or a coupler. The filter may be, for example, a surface acoustic wave filter, a bulk acoustic wave filter, or an LC filter. Optionally, the electronic component 4 may also be an electronic component including a plurality of filters.

The electronic component 4 includes a plurality of terminals 47 (refer to FIG. 4). The plurality of terminals 47 includes a plurality of signal terminals serving as signal paths and a plurality of ground terminals. The plurality of terminals 47 are provided to be exposed on the principal surface 41 of the electronic component 4. The plurality of terminals 47 are arranged side by side in two directions which are perpendicular to each other. The electronic component 4 may be bonded to the rewiring portions (conductor portions) P1 of the first buildup layer 2 via a plurality of bonding portions 48, for example. A material for the plurality of bonding portions 48 may be, for example, solder. The plurality of bonding portions 48 may be constituent elements of the electronic component 4 or constituent elements interposed between the electronic components 6 and the rewiring portions (conductor portions) P1 of the first buildup layer 2, whichever is appropriate. If the plurality of bonding portions 48 are constituent elements of the electronic component 4, then the plurality of bonding portions 48 are conductive bumps.

The electronic component 4 is disposed in a region, covering a central area of the core board 1, inside the through hole 14 of the core board 1. As used herein, the “central area of the core board 1” refers to a portion (region) covering at least the center of the core board 1 when viewed in plan in the thickness direction D1 defined for the core board 1. If the core board 1 has a rectangular shape, for example, then the center of the core board 1 is an intersection of two diagonals thereof. The “central area of the core board 1” preferably herein refers to a portion (region) covering the center of the core board 1 but not covering any end portion of the core board 1 when viewed in plan in the thickness direction D1 defined for the core board 1.

As shown in FIG. 2, in the thickness direction D1 defined for the core board 1, the thickness H1 of the electronic component 4 is greater than the thickness H2 of the core board 1. In other words, in the thickness direction D1 defined for the core board 1, the electronic component 4 is thicker than the core board 1. As used herein, the thickness H1 of the electronic component 4 refers to the distance between the principal surfaces 41, 42 of the electronic component 4. Also, in the example shown in FIGS. 1 and 2, in the thickness direction D1 defined for the core board 1, the principal surface 42 of the electronic component 4 and the principal surface 112 of the dielectric substrate 101 of the core board 1 are substantially flush with each other, and the principal surface 41 of the electronic component 4 is located closer to the first buildup layer 2 than the principal surface 111 of the dielectric substrate 101 of the core board 1 is.

As shown in FIG. 1, the electronic component 4 is electrically connected to the electronic component 6A via the first buildup layer 2. More specifically, the electronic component 4 is electrically connected to the electronic component 6A via the bonding portions 48, 66 and the rewiring portions P1, P2 and via conductors V1, V2 of the first buildup layer 2.

As can be seen from the foregoing description, this RF module 100 has a structure in which the electronic component 4 thicker than the core board 1 is disposed inside the through hole 14 of the core board 1 and the electronic components 4, 6 are arranged in two layers (at two different levels in the thickness direction D1 defined for the core board 1) and may still reduce the height of the overall module. In addition, disposing the electronic component 4 in the central area of the core board 1 enables reducing the warpage of the RF module 100 compared to disposing the electronic component at an end portion of the core board 1. Consequently, this contributes to both reducing the height of the overall module and ensuring a sufficient degree of planarity.

In the example shown in FIG. 1, the electronic component 6A is a chip capacitor and the electronic component 4 is an IC chip. The electronic component 6A is a constituent component of a matching circuit connected to the IC chip serving as the electronic component 4. In addition, the electronic component 6A overlaps with the electronic component 4 when viewed in plan in the thickness direction D1 defined for the core board 1. This may reduce the wire length between the electronic component 6A and the electronic component 4, thus reducing the chances of causing a decline in the characteristics.

Furthermore, in the thickness direction D1 defined for the core board 1, the electronic component 4 overlaps with the electronic components 7 arranged on the second buildup layer 3. This allows electronic components and terminals arranged in a region, not overlapping with the electronic component 4, of the second buildup layer 3 to be designed with an increased degree of freedom.

### (2.7) External Connection Terminals

The plurality of external connection terminals 9 are arranged on the second buildup layer 3. As used herein, the expression “the external connection terminals 9 are arranged on the second buildup layer 3” refers to both a situation where the external connection terminals 9 are mechanically connected to the second buildup layer 3 and a situation where the external connection terminals 9 are electrically connected to (appropriate rewiring portions P4 of) the second buildup layer 3. The plurality of external connection terminals 9 includes an antenna terminal connected to an antenna provided outside of the RF module 100, a signal input terminal connected to an input terminal of a power amplifier, and a signal output terminal connected to an output terminal of a low-noise amplifier. A material for the plurality of external connection terminals 9 may be, for example, a metal (such as copper or a copper alloy). Each of the plurality of external connection terminals 9 is a columnar electrode. The columnar electrode may be, for example, a circular columnar electrode. The plurality of external connection terminals 9 may be bonded, via solder, for example, to the rewiring portions P4 of the second buildup layer 3. However, this is only an example and should not be construed as limiting. Alternatively, the plurality of external connection terminals 9 may also be bonded to the rewiring portions P4 via a conductive adhesive (such as conductive paste) or bonded thereto directly, whichever is appropriate. Each of the plurality of external connection terminals 9 has a circular shape when viewed in plan in the thickness direction D1 defined for the core board 1.

### (2.8) First Resin Layer

The first resin layer 115 is disposed on the first buildup layer 2. The first resin layer 115 covers the plurality of electronic components 6 arranged on the first buildup layer 2. The first resin layer 115 contains a resin (such as an epoxy resin). The first resin layer 115 may contain not only the resin but also a filler as well.

### (2.9) Second Resin Layer

The second resin layer 116 is disposed on the second buildup layer 3. The second resin layer 116 covers the plurality of electronic components 7 arranged on the second buildup layer 3. In addition, the second resin layer 116 also covers the side surfaces of the plurality of external connection terminals 9. Nevertheless, the second resin layer 116 does not cover the end face 90, facing away from the second buildup layer 3, of the plurality of external connection terminals 9. The second resin layer 116 contains a resin (such as an epoxy resin). The second resin layer 116 may contain not only the resin but also a filler as well. A material for the second resin layer 116 may be the same as, or different from, the material for the first resin layer 115, whichever is appropriate.

### (3) Advantages

In the RF module 100 according to the first embodiment, an electronic component 4 (second electronic component) thicker than the core board 1 is disposed inside the through hole 14 of the core board 1. Thus, the RF module 100 has a structure in which the electronic components 4, 6, 7 are arranged in two or more layers (e.g., in three layers in the first embodiment) and may still reduce the height of the overall module. In addition, in the RF module 100 according to the first embodiment, the electronic component 4 is disposed in the central area of the core board 1, thus reducing the warpage of the RF module 100 compared to a situation where the electronic component is disposed at an end portion of the core board 1. Consequently, this contributes to both reducing the height of the overall module and ensuring a sufficient degree of planarity.

In particular, even if both surfaces of the wiring board 10 in the thickness direction D1 defined for the core board 1 are covered with the first resin layer 115 and the second resin layer 116, respectively, as in the RF module 100 according to the first embodiment, the warpage of the RF module 100 may also be reduced and a sufficient degree of planarity may also be ensured.

In the RF module 100 according to the first embodiment, the electronic component 6A (first electronic component) is a constituent component of a matching circuit connected to the electronic component 4 (second electronic component) and the electronic component 4 is an IC chip. This allows the wire length between the electronic component 6A and the electronic component 4 to be shortened, thus reducing the chances of causing a decline in the characteristics.

Also, in the RF module 100 according to the first embodiment, the electronic component 4 disposed inside the through hole 14 of the core board 1 overlaps with the electronic components 7 arranged on the second buildup layer 3. This allows the electronic components and terminals arranged in a region, not overlapping with any electronic component 7, of the second buildup layer 3 to be designed with increased degree of freedom.

### Second Embodiment

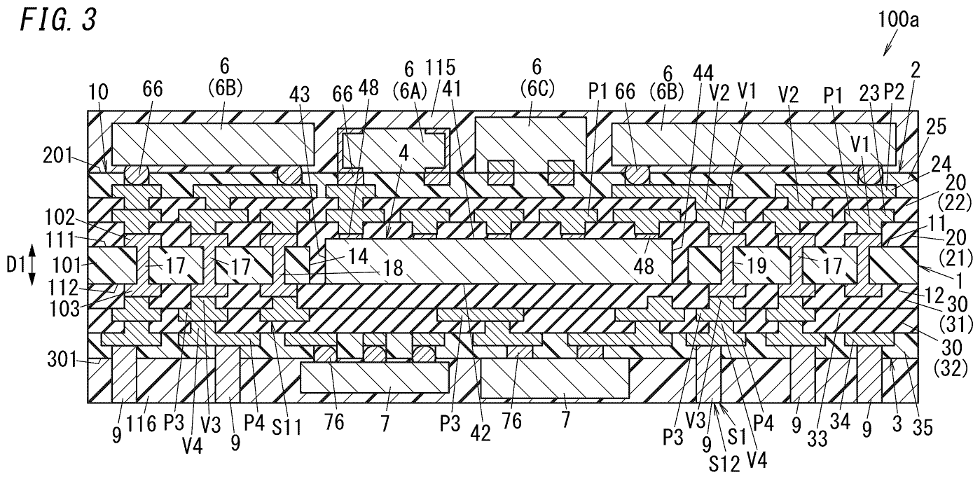

An RF module 100a according to a second embodiment will be described with reference to FIGS. 3 and 4. In the following description, any constituent element of the RF module 100a according to the second embodiment, having the same function as a counterpart of the RF module 100 (refer to FIG. 1) according to the first embodiment described above, will be designated by the same reference numeral as that counterpart's, and description thereof will be omitted herein.

### (1) Configuration

The RF module 100a according to the second embodiment includes, as the plurality of electronic components 6 arranged on the first buildup layer 2, electronic components 6A, 6B, 6C as shown in FIG. 3. The electronic component 6A is a chip capacitor. The electronic components 6B are IC chips. The electronic component 6C is a chip inductor. The electronic components 6A, 6C are constituent components of a matching circuit connected to the IC chip serving as the electronic component 4.

As shown in FIGS. 3 and 4, the RF module 100a according to the second embodiment further includes a shield portion S1. The shield portion S1 is built in the wiring board 10. The shield portion S1 includes a plurality of (e.g., four in the example illustrated in FIGS. 3 and 4) shield portions (namely, a first shield portion S11, a second shield portion S12, a third shield portion S13, and a fourth shield portion S14). The shield portion S1 includes feedthrough ground via conductors (including a first feedthrough ground via conductor 18, a second feedthrough ground via conductor 19, a third feedthrough ground via conductor 13, and a fourth feedthrough ground via conductor 16) which are arranged to surround the electronic component 4 when viewed in plan in the thickness direction D1 defined for the core board 1.

The first shield portion S11 includes a plurality of (e.g., two in the example illustrated in FIG. 4) first feedthrough ground via conductors 18. The plurality of first feedthrough ground via conductors 18 are provided for the core board 1 and are located in the vicinity of a side surface 43 of the electronic component 4. The plurality of first feedthrough ground via conductors 18 may be arranged side by side along the side surface 43 of the electronic component 4, for example. The second shield portion S12 includes a plurality of (e.g., two in the example illustrated in FIG. 4) second feedthrough ground via conductors 19. The plurality of second feedthrough ground via conductors 19 are provided for the core board 1 and are located in the vicinity of a side surface 44 of the electronic component 4. The plurality of second feedthrough ground via conductors 19 may be arranged side by side along the side surface 44 of the electronic component 4, for example.

The third shield portion S13 includes a plurality of (e.g., two in the example illustrated in FIG. 4) third feedthrough ground via conductors 13. The plurality of third feedthrough ground via conductors 13 are provided for the core board 1 and are located in the vicinity of a side surface 45 of the electronic component 4. The plurality of third feedthrough ground via conductors 13 may be arranged side by side along the side surface 45 of the electronic component 4, for example. The fourth shield portion S14 includes a plurality of (e.g., two in the example illustrated in FIG. 4) fourth feedthrough ground via conductors 16. The plurality of fourth feedthrough ground via conductors 16 are provided for the core board 1 and are located in the vicinity of a side surface 46 of the electronic component 4. The plurality of fourth feedthrough ground via conductors 16 may be arranged side by side along the side surface 46 of the electronic component 4, for example.

The first feedthrough ground via conductors 18, the second feedthrough ground via conductors 19, the third feedthrough ground via conductors 13, and the fourth feedthrough ground via conductors 16 penetrate through the dielectric substrate 101 of the core board 1. Each of the first feedthrough ground via conductors 18, the second feedthrough ground via conductors 19, the third feedthrough ground via conductors 13, and the fourth feedthrough ground via conductors 16 may have, for example, a circular columnar shape. A material for the first feedthrough ground via conductors 18, the second feedthrough ground via conductors 19, the third feedthrough ground via conductors 13, and the fourth feedthrough ground via conductors 16 may be the same as the material for the feedthrough via conductors 17 of the core board 1.

Each of the plurality of feedthrough ground via conductors (including the first feedthrough ground via conductors 18, the second feedthrough ground via conductors 19, the third feedthrough ground via conductors 13, and the fourth feedthrough ground via conductors 16) is disposed in the vicinity of a signal terminal 47A belonging to the plurality of terminals 47 of the electronic component 4 implemented as an IC chip. Specifically, the plurality of first feedthrough ground via conductors 18 are arranged in the vicinity of a plurality of signal terminals 47A arranged along the side surface 43 of the electronic component 4. The plurality of second feedthrough ground via conductors 19 are arranged in the vicinity of a plurality of signal terminals 47A arranged along the side surface 44 of the electronic component 4. The plurality of third feedthrough ground via conductors 13 are arranged in the vicinity of a plurality of signal terminals 47A arranged along the side surface 45 of the electronic component 4. The plurality of fourth feedthrough ground via conductors 16 are arranged in the vicinity of a plurality of signal terminals 47A arranged along the side surface 46 of the electronic component 4.

### (2) Advantages

In the RF module 100a according to the second embodiment, the first feedthrough ground via conductors 18, the second feedthrough ground via conductors 19, the third feedthrough ground via conductors 13, and the fourth feedthrough ground via conductors 16 (feedthrough ground via conductors) of the shield portion S1 are arranged to surround the electronic component 4 (second electronic component) disposed on the core board 1. This may reduce the chances of another electronic component interfering with the electronic component 4, thus reducing the variation in the characteristics due to the influence of another electronic component on the electronic component 4. In addition, reducing the interference of the electronic component 4 with another electronic component enables reducing the variation in the characteristics due to the influence of the electronic component 4 on another electronic component.

### Third Embodiment

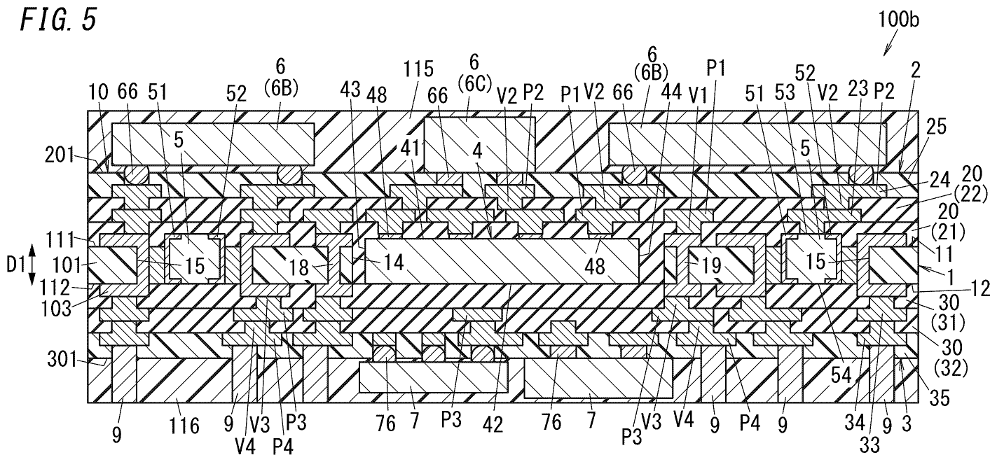

An RF module 100b according to a third embodiment will be described with reference to FIG. 5. In the following description, any constituent element of the RF module 100b according to the third embodiment, having the same function as a counterpart of the RF module 100a (refer to FIG. 3) according to the second embodiment described above, will be designated by the same reference numeral as that counterpart's, and description thereof will be omitted herein.

### (1) Configuration

As shown in FIG. 5, the RF module 100b according to the third embodiment further includes a plurality of electronic components 5 (as third electronic components). The plurality of electronic components 5 are built in the wiring board 10.

The core board 1 further has a plurality of second through holes 15, which are different from the through hole 14 (first through hole). The plurality of second through holes 15 are provided through a peripheral portion of the core board 1 when viewed in plan in the thickness direction D1 defined for the core board 1. That is to say, the plurality of second through holes 15 are located closer to the periphery of the core board 1 than the through hole 14 is. The plurality of second through holes 15 are provided through the core board 1 to be located on mutually opposite sides with the through hole 14 interposed between themselves.

Of the electronic components 6 arranged on the wiring board 10, the electronic components 6B (fourth electronic components) are IC chips and the electronic component 6C is an inductor.

The plurality of electronic components 5 are disposed inside the plurality of second through holes 15 of the core board 1. More specifically, the plurality of electronic components 5 are disposed inside their corresponding through holes 15 of the core board 1 with the electronic component 4 interposed between themselves.

The electronic components 5 are chip capacitors. The chip capacitors serving as the electronic components 5 are constituent components of a matching circuit connected to the IC chip serving as the electronic component 6B. Each of the electronic components 5 includes a first electrode 51 and a second electrode 52. Each electronic component 5 has a substantially rectangular parallelepiped outer shape. Either a part of the first dielectric layer 20 or a conductor of the first buildup layer 2 is located between each electronic component 5 and the inner peripheral surface of a corresponding one of the second through holes 15 of the core board 1. Each electronic component 5 has two principal surfaces 53, 54 facing each other in the thickness direction D1 defined for the core board 1. The electronic components 5 are connected to the electronic components 6B belonging to the plurality of electronic components 6. The electronic components 6B, to which a matching circuit including chip capacitors serving as the electronic components 5 is connected, may be, for example, a power amplifier, a low-noise amplifier, a filter, or a switch. As used herein, the switch refers to a switch integrated circuit (IC) including a common terminal and a plurality of selection terminals which may be connected to the common terminal.

Each electronic component 5 has a smaller area than the electronic component 4 when viewed in plan in the thickness direction D1 defined for the core board 1. Each electronic component 5 is higher (thicker) than the core board 1 in the thickness direction D1 defined for the core board 1. As used herein, the thickness of the electronic component 5 refers to the distance between the principal surfaces 53, 54 of the electronic component 5. Also, in the example shown in FIG. 5, in the thickness direction D1 defined for the core board 1, the principal surface 54 of each electronic component 5 and the principal surface 112 of the dielectric substrate 101 of the core board 1 are substantially flush with each other and the principal surface 53 of each electronic component 5 is located closer to the first buildup layer 2 than the principal surface 111 of the dielectric substrate 101 of the core board 1 is.

### (2) Advantages

In the RF module 100b according to the third embodiment, electronic components 5 (third electronic components) each having a smaller area than the electronic component 4 (second electronic component) when viewed in plan in the thickness direction D1 defined for the core board 1 are disposed inside the through holes 15 of the core board 1. This allows a larger number of electronic components (electronic components 4, 5) to be arranged on the core board 1.

In the RF module 100b according to the third embodiment, the electronic component 6B (fourth electronic component) is an IC chip and the electronic components 5 (third electronic components) are chip capacitors which forms part of a matching circuit connected to the IC chip serving as the electronic component 6B. This allows the wire length between each of the electronic components 5 and the electronic component 6B to be shortened, thus reducing the chances of causing a decline in the characteristics thereof.

### Fourth Embodiment

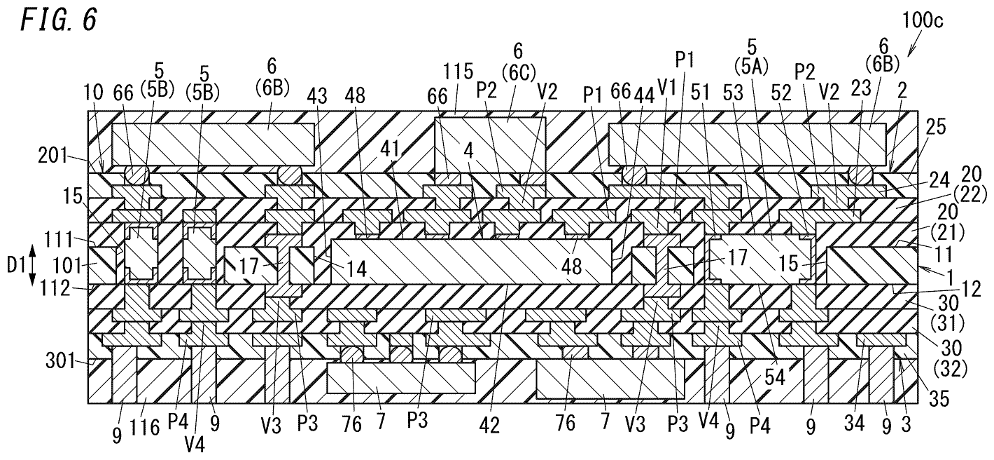

An RF module 100c according to a fourth embodiment will be described with reference to FIG. 6. In the following description, any constituent element of the RF module 100c according to the fourth embodiment, having the same function as a counterpart of the RF module 100b (refer to FIG. 5) according to the third embodiment described above, will be designated by the same reference numeral as that counterpart's, and description thereof will be omitted herein.

### (1) Configuration

The RF module 100c according to the fourth embodiment includes, as electronic components 5 (third electronic components), a transverse mounted chip capacitor 5A and a plurality of (e.g., two in the example shown in FIG. 6) longitudinally mounted chip capacitors 5B as shown in FIG. 6. In the example shown in FIG. 6, the transverse mounted chip capacitor 5A and the plurality of longitudinally mounted chip capacitors 5B are arranged on two opposite sides of the electronic component 4 on the core board 1. The plurality of longitudinally mounted chip capacitors 5B are arranged adjacent to each other.

### (2) Advantages

In the RF module 100c according to the fourth embodiment, the transverse mounted chip capacitor 5A and the longitudinally mounted chip capacitors 5B are arranged to surround the electronic component 4 (second electronic component) on the core board 1.

This RF module 100c accepts not only the transverse mounted chip capacitor 5A but also the longitudinally mounted chip capacitors 5B as well, thus allowing the electronic components 5 built in the wiring board 10 to be designed with an increased degree of freedom.

### (Variations of Fourth Embodiment)

According to a variation of the fourth embodiment, the number of the transverse mounted chip capacitors 5A arranged on the core board 1 does not have to be one but may also be two or more. According to another variation of the fourth embodiment, the number of the longitudinally mounted chip capacitors 5B arranged on the core board 1 does not have to be two but may also be one or three or more.

This RF module 100c according to any of these variations of the fourth embodiment also accepts not only the transverse mounted chip capacitor 5A but also the longitudinally mounted chip capacitors 5B as well, thus allowing the electronic components 5 built in the wiring board 10 to be designed with an increased degree of freedom.

### Fifth Embodiment

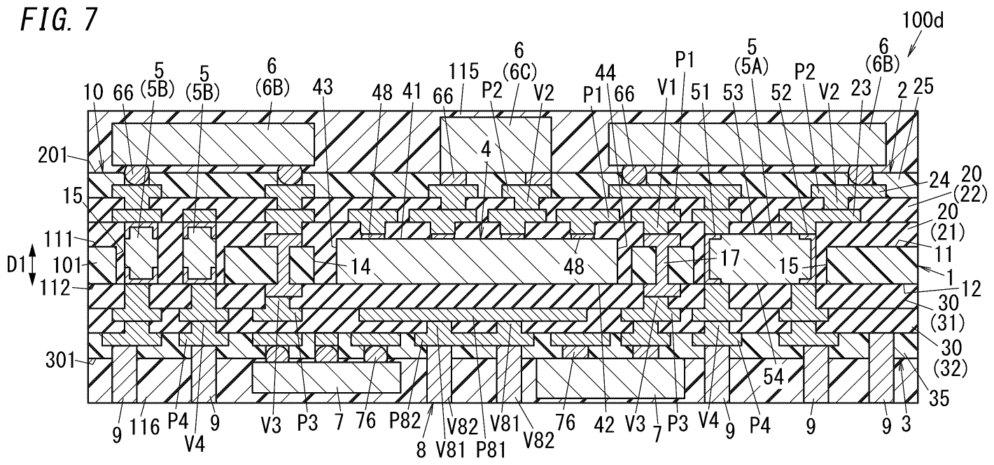

An RF module 100d according to a fifth embodiment will be described with reference to FIG. 7. In the following description, any constituent element of the RF module 100d according to the fifth embodiment, having the same function as a counterpart of the RF module 100 (refer to FIG. 1) according to the first embodiment described above, will be designated by the same reference numeral as that counterpart's, and description thereof will be omitted herein.

### (1) Configuration

The RF module 100d according to the fifth embodiment further includes a heat dissipating portion 8 as shown in FIG. 7. The heat dissipating portion 8 overlaps with the electronic component 4 (second electronic component) when viewed in plan in the thickness direction D1 defined for the core board 1.

The heat dissipating portion 8 includes a plurality of conductor portions P81, P82 and a plurality of via conductors V81, V82. The plurality of conductor portions P81, P82 and the plurality of via conductors V81, V82 are provided for the second buildup layer 3. More specifically, the conductor portions P81, P82 and the via conductors V81, V82 are built in the second buildup layer 3. The via conductors V82 are arranged on the second buildup layer 3. The plurality of via conductors V81 penetrate through the second dielectric layer 32. The conductor portion P81 is formed on the second dielectric layer 31 and is connected to the via conductors V81. The conductor portion P81 overlaps with the electronic component 4 when viewed in plan in the thickness direction D1 defined for the core board 1. The conductor portion P82 is formed on the second dielectric layer 32 and is connected to the via conductors V82. A material for the conductor portion P81 is the same as the material for the rewiring portions P3. A material for the conductor portion P82 and the via conductors V81 is the same as the material for the rewiring portions P4 and the via conductors V4. A material for the via conductors V82 is the same as the material for the external connection terminals 9.

The heat dissipating portion 8 is out of contact with the electronic component 4 in the thickness direction D1 defined for the core board 1. More specifically, the conductor portion P81 of the heat dissipating portion 8 is arranged to face, and be out of contact with, the electronic component 4 in the thickness direction D1 defined for the core board 1.

The heat generated by the electronic component 4 is dissipated to an external space through the heat dissipating portion 8. More specifically, the heat generated by the electronic component 4 is dissipated via the conductor portion P81, the via conductors V81, the conductor portion P82, and the via conductors V82.

### (2) Advantages

In the RF module 100c according to the fifth embodiment, the heat dissipating portion 8 overlaps with the electronic component 4 (second electronic component). This allows the heat generated by the electronic component 4 disposed on the core board 1 to be dissipated more efficiently.

In addition, in the RF module 100d according to the fifth embodiment, the heat dissipating portion 8 is out of contact with the electronic component 4 (second electronic component). This reduces the chances of doing damage to the electronic component 4 when the heat dissipating portion 8 is formed. More specifically, there is no need to provide any through hole through the second dielectric layer 30 when the heat dissipating portion 8 is formed. Thus, when a through hole is cut through the second dielectric layer 31 with a laser beam, the laser beam does not reach the electronic component 4. This reduces the chances of causing damage to the electronic component with the laser beam reaching the electronic component 4.

### (Variation of Fifth Embodiment)

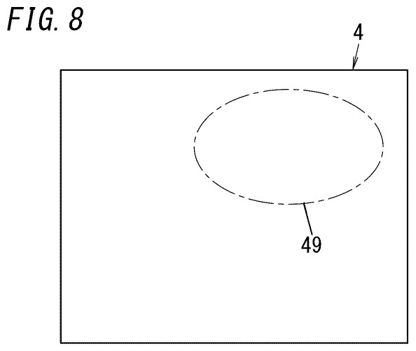

According to a variation of the fifth embodiment, the heat dissipating portion 8 may also be arranged to overlap with a part of the electronic component 4. For example, if the electronic component 4 has any part 49 where the temperature tends to rise easily as shown in FIG. 8, then the heat dissipating portion 8 is arranged to overlap with such a part 49 where the temperature tends to rise easily.

The RF module 100d according to this variation of the fifth embodiment may enhance the heat dissipation effect even if the size of the heat dissipating portion 8 is decreased.

### Sixth Embodiment

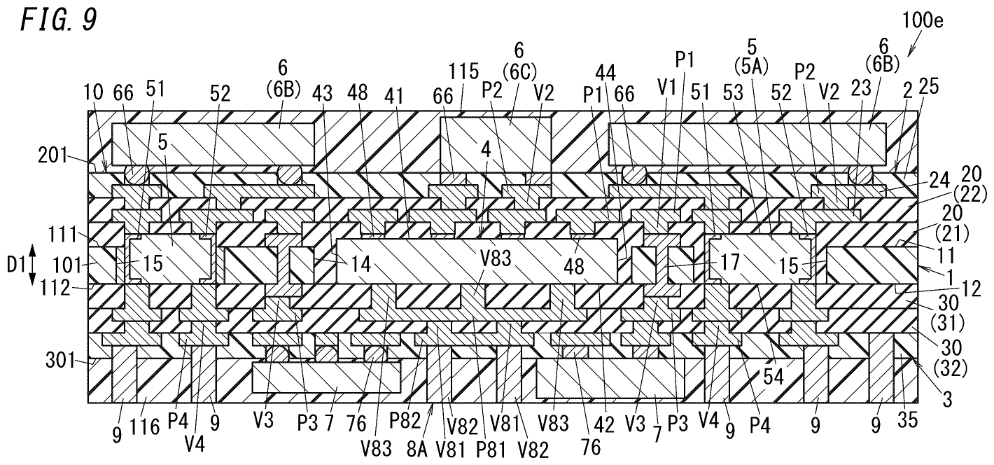

An RF module 100e according to a sixth embodiment will be described with reference to FIG. 9. In the following description, any constituent element of the RF module 100e according to the sixth embodiment, having the same function as a counterpart of the RF module 100d (refer to FIG. 7) according to the fifth embodiment described above, will be designated by the same reference numeral as that counterpart's, and description thereof will be omitted herein.

### (1) Configuration

As shown in FIG. 9, the RF module 100e according to the sixth embodiment includes a heat dissipating portion 8A instead of the heat dissipating portion 8 according to the fifth embodiment. The heat dissipating portion 8A, as well as the heat dissipating portion 8 according to the fifth embodiment, also overlaps with the electronic component 4 (second electronic component) when viewed in plan in the thickness direction D1 defined for the core board 1.

The heat dissipating portion 8A includes a plurality of conductor portions P81, P82 and a plurality of via conductors V81, V82, V83. The plurality of conductor portions P81, P82 and the plurality of via conductors V81-V83 are provided for the second buildup layer 3. More specifically, the conductor portions P81, P82 and the via conductors V81, V83 are built in the second buildup layer 3. The via conductors V82 are arranged on the second buildup layer 3. The plurality of via conductors V81 penetrate through the second dielectric layer 32. The plurality of via conductors V83 penetrate through the second dielectric layer 31. The conductor portion P81 is formed on the second dielectric layer 31 and is connected to the via conductors V81, V83. The conductor portion P81 overlaps with the electronic component 4 when viewed in plan in the thickness direction D1 defined for the core board 1. A material for the conductor portion P81 and the via conductors V83 is the same as the material for the rewiring portions P3 and the via conductors V3. The conductor portion P82 is formed on the second dielectric layer 32 and is connected to the via conductors V82. A material for the conductor portion P82 and the via conductors V81 is the same as the material for the rewiring portions P4 and the via conductors V4. A material for the via conductors V82 is the same as the material for the external connection terminals 9.

The heat dissipating portion 8A is in contact with the electronic component 4 (second electronic component) in the thickness direction D1 defined for the core board 1. More specifically, in the thickness direction D1 defined for the core board 1, the via conductors V83 of the heat dissipating portion 8A connect the electronic component 4 to the conductor portion P81.

The heat generated by the electronic component 4 is dissipated to an external space through the heat dissipating portion 8A. More specifically, the heat generated by the electronic component 4 is dissipated via the via conductors V83, the conductor portion P81, the via conductors V81, the conductor portion P82, and the via conductors V82.

### (2) Advantages

In the RF module 100e according to the sixth embodiment, the heat dissipating portion 8A is in contact with the electronic component 4 (second electronic component). This allows the heat generated by the electronic component 4 to be dissipated more efficiently.

### Seventh Embodiment

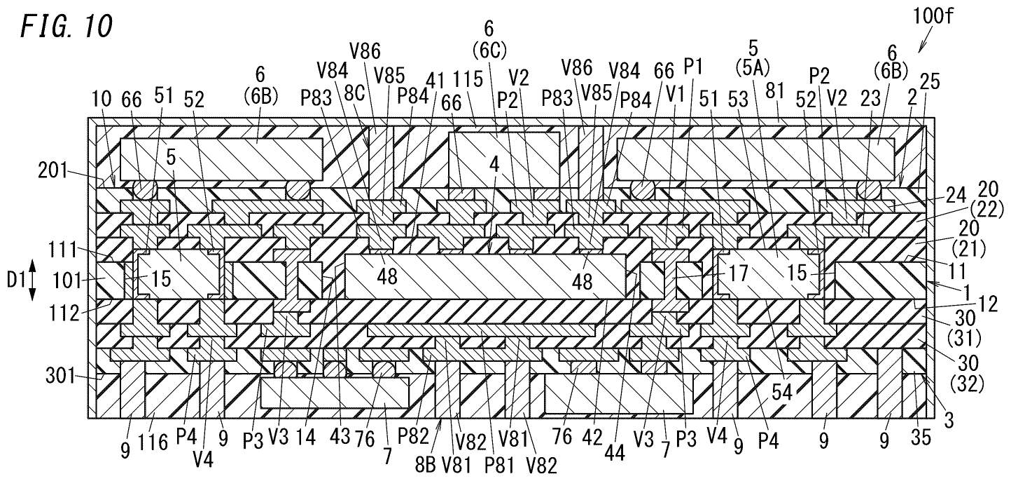

An RF module 100f according to a seventh embodiment will be described with reference to FIG. 10. In the following description, any constituent element of the RF module 100f according to this seventh embodiment, having the same function as a counterpart of the RF module 100d (refer to FIG. 7) according to the fifth embodiment described above, will be designated by the same reference numeral as that counterpart's, and description thereof will be omitted herein.

### (1) Configuration

The RF module 100f according to the seventh embodiment further includes a shield layer 81, a first heat dissipating portion 8B, and a second heat dissipating portion 8C, which is different from the first heat dissipating portion 8B.

The first heat dissipating portion 8B, as well as the heat dissipating portion 8 (refer to FIG. 7) according to the fifth embodiment, includes the plurality of conductor portions P81, P82 and the plurality of via conductors V81, V82. The first heat dissipating portion 8B has the same function as the heat dissipating portion 8, and therefore, description thereof will be omitted herein.

The shield layer 81 may be connected to a ground terminal, which is included in the plurality of external connection terminals 9, via a ground electrode of the core board 1, for example. The shield layer 81 has electrical conductivity. In this RF module 100f, the shield layer 81 is provided as an electromagnetic shield inside and outside of the RF module 100f. The shield layer 81 may have, for example, a multilayer structure in which a plurality of metal layers are stacked one on top of another. However, this is only an example and should not be construed as limiting. Alternatively, the shield layer 81 may consist of a single metal layer. The metal layer contains either a single type of metal or multiple types of metals, whichever is appropriate. If the shield layer 81 has a multilayer structure in which a plurality of metal layers are stacked one on top of another, the shield layer 81 may include, for example, a first stainless steel layer, a Cu layer stacked on the first stainless steel layer, and a second stainless steel layer stacked on the Cu layer. A material for each of the first stainless steel layer and the second stainless steel layer is an alloy including Fe, Ni, and Cr. On the other hand, if the shield layer 81 is implemented as a single metal layer, then the shield layer 81 may be a Cu layer, for example.

The second heat dissipating portion 8C includes a plurality of conductor portions P83, P84 and a plurality of via conductors V84, V85, V86. The plurality of conductor portions P83, P84 and the plurality of via conductors V84-V86 are provided for the first buildup layer 2. More specifically, the conductor portions P83, P84 and the via conductors V84, V85 are built in the first buildup layer 2. The via conductors V86 are arranged on the first buildup layer 2. The plurality of via conductors V84 penetrate through the first dielectric layer 21. The plurality of via conductors V85 penetrate through the first dielectric layer 22. The conductor portions P83 are formed on the first dielectric layer 21 and are connected to the via conductors V84, V85. The conductor portions P84 are formed on the first dielectric layer 22 and are connected to the via conductors V85, V86. A material for the conductor portions P83 and the via conductors V84 is the same as the material for the rewiring portions P1 and the via conductors V1. A material for the conductor portions P84 and the via conductors V85 is the same as the material for the rewiring portions P2 and the via conductors V2.

The second heat dissipating portion 8C overlaps with the electronic component 4 (second electronic component) when viewed in plan in the thickness direction D1 defined for the core board 1. In addition, the second heat dissipating portion 8C is in contact with the shield layer 81. The second heat dissipating portion 8C connects the electronic component 4 to the shield layer 81.

The heat generated by the electronic component 4 is dissipated to an external space through the second heat dissipating portion 8C and the shield layer 81. More specifically, the heat generated by the electronic component 4 is transferred to the shield layer 81 via the via conductors V84, the conductor portions P83, the via conductors V85, the conductor portions P84, and the via conductors V86. Then, the heat transferred to the shield layer 81 is dissipated to the external space. As can be seen from the foregoing description, the shield layer 81 performs both a shielding function and a heat dissipating function.

### (2) Advantages

The RF module 100f according to the seventh embodiment is provided with the first heat dissipating portion 8B and the second heat dissipating portion 8C having mutually different heat dissipation paths. This allows the heat generated by the electronic component 4 (second electronic component) to be dissipated even more efficiently.

### (First Variation of Seventh Embodiment)

According to a first variation of the seventh embodiment, the RF module 100f may include only the second heat dissipating portion 8C out of the first heat dissipating portion 8B and the second heat dissipating portion 8C. The RF module 100f according to the first variation of the seventh embodiment may also more efficiently dissipate the heat generated by the electronic component 4 (second electronic component).

### (Second Variation of Seventh Embodiment)

According to a second variation of the seventh embodiment, the RF module 100f may include the heat dissipating portion 8A (refer to FIG. 9) according to the sixth embodiment instead of the first heat dissipating portion 8B. The RF module 100f according to the second variation of the seventh embodiment may also more efficiently dissipate the heat generated by the electronic component 4 (second electronic component).

### Eighth Embodiment

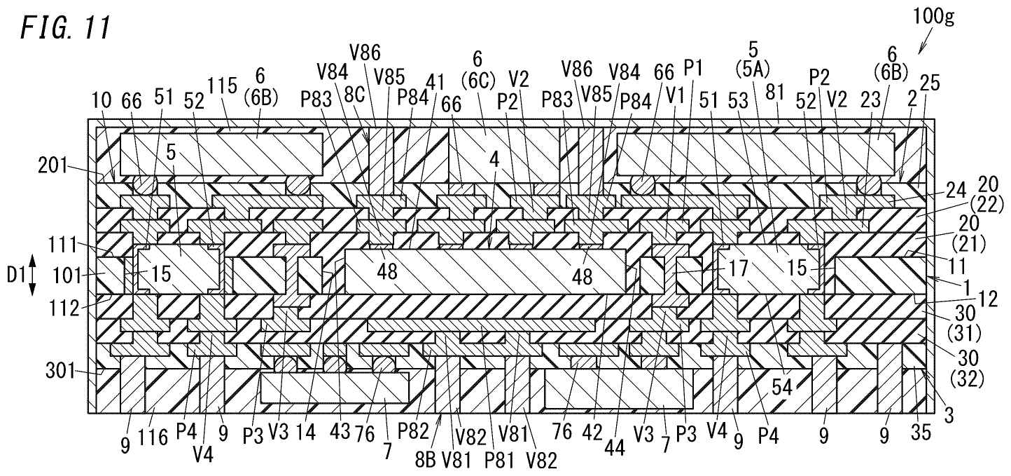

An RF module 100g according to an eighth embodiment will be described with reference to FIG. 11. In the following description, any constituent element of the RF module 100g according to the eighth embodiment, having the same function as a counterpart of the RF module 100f (refer to FIG. 10) according to the seventh embodiment described above, will be designated by the same reference numeral as that counterpart's, and description thereof will be omitted herein.

### (1) Configuration

In the RF module 100g according to the eighth embodiment, one principal surface, opposite from the other principal surface facing the first buildup layer 2, of at least one electronic component 6 belonging to the plurality of electronic components 6 is not covered with the first resin layer 115 but is in contact with the shield layer 81. In the example shown in FIG. 11, an electronic component 6C belonging to the plurality of electronic components 6 is in contact with the shield layer 81. On the other hand, the other electronic components 6B belonging to the plurality of electronic components 6 are not in contact with the shield layer 81.

### (2) Advantages

In the RF module 100g according to the eighth embodiment, the electronic component 6C is in contact with the shield layer 81. This makes it easier to transfer the heat from the electronic component 8C to the shield layer 81, thus allowing the heat generated by the electronic component 6C to be dissipated more efficiently.

### (Variation of Eighth Embodiment)

According to a variation of the eighth embodiment, in the RF module 100g, at least one electronic component 6, other than the electronic component 6C, may be in contact with the shield layer 81. For example, all of the plurality of electronic components 6 may be in contact with the shield layer 81. Alternatively, only the electronic components 6B belonging to the plurality of electronic component 6 may be in contact with the shield layer 81 and the electronic component 8C may be out of contact with the shield layer 81. In short, at least one of the plurality of electronic components 6 may be in contact with the shield layer 81.

The RF module 100g according to this variation of the eighth embodiment makes it easier to transfer the heat from the electronic component 6 in contact with the shield layer 81 to the shield layer 81, thus allowing the heat generated by the electronic component 6 in contact with the shield layer 81 to be dissipated more efficiently.

### (Other Variations)

Note that the first to eighth embodiments described above are only exemplary ones of various embodiments of the present disclosure and should not be construed as limiting. Rather, the first to eighth embodiments may be readily modified in various manners depending on a design choice or any other factor without departing from the scope of the present disclosure. Optionally, multiple different constituent elements of mutually different embodiments may be adopted in combination as appropriate.

For example, the core board 1 does not have to be a double-sided printed wiring board but may also be a low temperature co-fired ceramic board, for example.

Also, in the RF modules 100, 100a, 100b, 100c, 100d, 100e, 100f, 100g, each of the plurality of external connection terminals 9 may also be a ball bump with electrical conductivity. Examples of materials for the ball bump serving as each of the plurality of external connection terminals 9 include gold, copper, and solder.

The RF modules 100, 100a, 100b, 100c, 100d, 100e, 100f, 100g each include electronic components 7 mounted on the principal surface 301 of the second buildup layer 3. However, this is only an example and should not be construed as limiting. Alternatively, the RF modules 100, 100a, 100b, 100c, 100d, 100e, 100f, 100g may each be configured such that the electronic components 7 are arranged on the principal surface 201 of the first buildup layer 2 with no electronic components 7 mounted on the principal surface 301 of the second buildup layer 3.

Furthermore, the RF modules 100, 100a, 100b, 100c, 100d, 100e, 100f, 100g may each be implemented as, for example, a transmission/reception module including a power amplifier, a transmission filter, an output matching circuit, a low-noise amplifier, a reception filter, and an input matching circuit. However, this is only an example and should not be construed as limiting. Alternatively, the RF modules 100, 100a, 100b, 100c, 100d, 100e, 100f, 100g may each be, for example, a transmission module including a power amplifier, a transmission filter, and an output matching circuit or a reception module including a low-noise amplifier, a reception filter, and an input matching circuit.

Furthermore, in the RF modules 100, 100a, 100b, 100c, 100d, 100e, 100f, 100g described above, the electronic component 6A, 6C is supposed to be a circuit element of a matching circuit connected to the IC chip serving as the electronic component 4. Alternatively, the electronic component 6A may also be a decoupling capacitor, a coupling capacitor, or a bypass capacitor.

### (Aspects)

The foregoing description of first to eighth embodiments and their variations provides specific implementations of the following aspects of the present disclosure.

A radio frequency module (100; 100a; 100b; 100c; 100d; 100e; 100f, 100g) according to a first aspect includes a wiring board (10), a first electronic component (electronic component 6A; 6C), and a second electronic component (electronic component 4). The first electronic component is disposed on the wiring board (10). The second electronic component is built in the wiring board (10). The wiring board (10) includes a core board (1), a first buildup layer (2), and a second buildup layer (3). The core board (1) has a first principal surface (11) and a second principal surface (12) facing each other. The first buildup layer (2) is stacked on the first principal surface (11) of the core board (1). The second buildup layer (3) is stacked on the second principal surface (12) of the core board (1). The core board (1) has a through hole (14). The first electronic component is arranged on the first buildup layer (2) to overlap with the through hole (14) of the core board (1) when viewed in plan in a thickness direction (D1) defined for the core board (1). The second electronic component is disposed inside the through hole (14) of the core board (1). Thickness (H1) of the second electronic component is greater than thickness (H2) of the core board (1) when measured in the thickness direction (D1) defined for the core board (1). The second electronic component is electrically connected to the first electronic component via the first buildup layer (2).

The radio frequency module (100; 100a; 100b; 100c; 100d; 100e; 100f, 100g) according to the first aspect has a structure in which the electronic components (4, 6A, 6C) are arranged in two layers and may still reduce the height of the overall module. In addition, the radio frequency module (100; 100a; 100b; 100c; 100d; 100e; 100f, 100g) according to the first aspect may also reduce the warpage of the radio frequency module (100; 100a; 100b; 100c; 100d; 100e; 100f, 100g) compared to a situation where the second electronic component is disposed at an end portion of the core board (1). Consequently, this contributes to both reducing the height of the overall module and ensuring a sufficient degree of planarity.

In a radio frequency module (100; 100a; 100b; 100c; 100d; 100e; 100f, 100g) according to a second aspect, which may be implemented in conjunction with the first aspect, the through hole (14) of the core board (1) is provided through a central area of the core board (1) when viewed in plan in the thickness direction (D1) defined for the core board (1). The second electronic component (electronic component 4) is disposed in a region, covering the central area of the core board (1), inside the through hole (14) of the core board (1).

In a radio frequency module (100; 100a; 100b; 100c; 100d; 100e; 100f, 100g) according to a third aspect, which may be implemented in conjunction with the first or second aspect, the second electronic component (electronic component 4) is an IC chip. The first electronic component (electronic component 6A; 6C) is a constituent component of a matching circuit connected to the second electronic component.

The radio frequency module (100; 100a; 100b; 100c; 100d; 100e; 100f, 100g) according to the third aspect may shorten the wire length between the first electronic component (electronic component 6A; 6C) and the second electronic component (electronic component 4), thus reducing the chances of causing a decline in its characteristics.

A radio frequency module (100a; 100b; 100c) according to a fourth aspect, which may be implemented in conjunction with the third aspect, further includes a shield portion (S1). The shield portion (S1) is built in the wiring board (10). The shield portion (S1) includes a feedthrough ground via conductor (such as a third feedthrough ground via conductor 13, a fourth feedthrough ground via conductor 16, a first feedthrough ground via conductor 18, or a second feedthrough ground via conductor 19). The feedthrough ground via conductor is arranged to surround the second electronic component (electronic component 4) when viewed in plan in the thickness direction (D1) defined for the core board (1).

The radio frequency module (100a; 100b; 100c) according to the fourth aspect may reduce the chances of another electronic component interfering with the second electronic component (electronic component 4), thus reducing the variation in the characteristics due to the influence of another electronic component on the second electronic component. In addition, reducing the interference of the second electronic component with another electronic component enables reducing the variation in the characteristics due to the influence of the second electronic component on another electronic component.

A radio frequency module (100b; 100c; 100d; 100e; 100f, 100g) according to a fifth aspect, which may be implemented in conjunction with any one of the first to fourth aspects, further includes a third electronic component (electronic component 5). The third electronic component is built in the wiring board (10). The core board (1) further has a second through hole (15) different from a first through hole serving as the through hole (14). The third electronic component is disposed inside the second through hole (15) of the core board (1). The third electronic component has a smaller area than the second electronic component (electronic component 4) when viewed in plan in the thickness direction (D1) defined for the core board (1).

The radio frequency module (100b; 100c; 100d; 100e; 100f, 100g) according to the fifth aspect allows a larger number of electronic components (4, 5) to be arranged on the core board (1).

A radio frequency module (100b; 100c; 100d; 100e; 100f, 100g) according to a sixth aspect, which may be implemented in conjunction with the fifth aspect, further includes a fourth electronic component (electronic component 6B). The fourth electronic component is disposed on the wiring board (10). The fourth electronic component is an IC chip. The third electronic component (electronic component 5) is a chip capacitor and is a constituent component of a matching circuit connected to the fourth electronic component.

The radio frequency module (100b; 100c; 100d; 100e; 100f, 100g) according to the sixth aspect may shorten the wire length between the third electronic component (electronic component 5) and the fourth electronic component (electronic component 6B), thus reducing the chances of causing a decline in its characteristics.

A radio frequency module (100c; 100d) according to a seventh aspect, which may be implemented in conjunction with the sixth aspect, includes, as a plurality of the third electronic components (electronic components 5), a transverse mounted chip capacitor (5A) and a longitudinally mounted chip capacitor (5B).

The radio frequency module (100c; 100d) according to the seventh aspect allows the electronic components (5) built in the wiring board (10) to be designed with an increased degree of freedom.

A radio frequency module (100d; 100e; 100f, 100g) according to an eighth aspect, which may be implemented in conjunction with any one of the first to seventh aspects, further includes a heat dissipating portion (8; 8A; 8B). The heat dissipating portion (8; 8A; 8B) overlaps with the second electronic component (electronic component 4) when viewed in plan in the thickness direction (D1) defined for the core board (1).

The radio frequency module (100d; 100e; 100f, 100g) according to the eighth aspect allows the heat generated by the second electronic component (electronic component 4) disposed on the core board (1) to be dissipated more efficiently.

In a radio frequency module (100d; 100f, 100g) according to a ninth aspect, which may be implemented in conjunction with the eighth aspect, the heat dissipating portion (8; 8B) is out of contact with the second electronic component (electronic component 4) in the thickness direction (D1) defined for the core board (1).

The radio frequency module (100d; 100f, 100g) according to the ninth aspect may reduce, when the heat dissipating portion (8; 8B) is formed, the chances of doing damage to the second electronic component (electronic component 4).

In a radio frequency module (100e) according to a tenth aspect, which may be implemented in conjunction with the eighth aspect, the heat dissipating portion (8A) is in contact with the second electronic component (electronic component 4) in the thickness direction (D1) defined for the core board (1).

The radio frequency module (100e) according to the tenth aspect allows the heat generated by the second electronic component (electronic component 4) to be dissipated more efficiently.

A radio frequency module (100f, 100g) according to an eleventh aspect, which may be implemented in conjunction with the ninth or tenth aspect, further includes a shield layer (81) and a second heat dissipating portion (8C) different from a first heat dissipating portion (8B) serving as the heat dissipating portion. The second heat dissipating portion (8C) overlaps with the second electronic component (electronic component 4) when viewed in plan in the thickness direction (D1) defined for the core board (1). The second heat dissipating portion (8C) is in contact with the shield layer (81).

The radio frequency module (100f, 100g) according to the eleventh aspect allows the heat generated by the second electronic component (electronic component 4) to be dissipated even more efficiently.

A radio frequency module (100; 100a; 100b; 100c; 100d; 100e; 100f, 100g) according to a twelfth aspect, which may be implemented in conjunction with any one of the first to eleventh aspects, further includes an electronic component (7). The electronic component (7) is disposed on the second buildup layer (3). The second electronic component (electronic component 4) overlaps with the electronic component (7) disposed on the second buildup layer (3) in the thickness direction (D1) defined for the core board (1).

The radio frequency module (100; 100a; 100b; 100c; 100d; 100e; 100f, 100g) according to the twelfth aspect may be designed with an increased degree of freedom.
1 Core Board
11 First Principal Surface
12 Second Principal Surface
13 Third Feedthrough Ground Via Conductor
14 Through Hole (First Through Hole)
15 Second Through Hole
16 Fourth Feedthrough Ground Via Conductor
17 Feedthrough Via Conductors
18 First Feedthrough Ground Via Conductor
19 Second Feedthrough Ground Via Conductor
101 Dielectric Substrate
102 First Conductive Layer
103 Second Conductive Layer
111, 112 Principal Surface
2 First Buildup Layer
20, 21, 22 First Dielectric Layer
23, 24 First Conductor Layer
25 First Resist Layer
201 Principal Surface
3 Second Buildup Layer
30, 31, 32 Second Dielectric Layer
33, 34 Second Conductor Layer
Second Resist Layer
301 Principal Surface
4 Electronic Component (Second Electronic Component)
41, 42 Principal Surface
43, 44, 45, 46 Side Surface
47 Terminal
47A Signal Terminal
48 Bonding Portion
49 Part Where Temperature Tends to Rise Easily
5 Electronic Component (Third Electronic Component)
5A Transverse Mounted Chip Capacitor
5B Longitudinally Mounted Chip Capacitor
51 First Electrode
52 Second Electrode
53, 54 Principal Surface
6 Electronic Component
6A, 6C Electronic Component (First Electronic Component)
6B Electronic Component (Fourth Electronic Component)
66 Bonding Portion
7 Electronic Component
76 Bonding Portion
8, 8A Heat Dissipating Portion
8B First Heat Dissipating Portion
8C Second Heat Dissipating Portion
81 Shield Layer
9 External Connection Terminal
90 End Face
10 Wiring Board
100, 100a, 100b, 100c, 100d, 100e, 100f, 100g RF Module
115 First Resin Layer
116 Second Resin Layer
D1 Thickness Direction
H1 Thickness
H2 Thickness
P1, P2, P3, P4 Rewiring Portion
P81, P82, P83, P84 Conductor Portion
S1 Shield Portion
S11 First Shield Portion
S12 Second Shield Portion
S13 Third Shield Portion
S14 Fourth Shield Portion
V1, V2, V3, V4 Via Conductor
V81, V82, V83, V84, V85, V86 Via Conductor

1. A radio frequency module comprising:
a wiring board;
a first electronic component disposed on the wiring board; and
a second electronic component built in the wiring board,
the wiring board including:
a core board having a first principal surface and a second principal surface facing each other;
a first buildup layer stacked on the first principal surface of the core board; and
a second buildup layer stacked on the second principal surface of the core board,
the core board having a through hole,
the first electronic component being arranged on the first buildup layer to overlap with the through hole of the core board when viewed in plan in a thickness direction defined for the core board,
the second electronic component being disposed inside the through hole of the core board,
a thickness of the second electronic component being greater than a thickness of the core board when measured in the thickness direction defined for the core board, and
the second electronic component being electrically connected to the first electronic component via the first buildup layer.

2. The radio frequency module of claim 1, wherein
the through hole of the core board is provided through a central area of the core board when viewed in plan in the thickness direction defined for the core board, and
the second electronic component is disposed in a region, covering the central area of the core board, inside the through hole of the core board.

3. The radio frequency module of claim 1, wherein
the second electronic component is an IC chip, and
the first electronic component is a constituent component of a matching circuit connected to the second electronic component.

4. The radio frequency module of claim 3, further comprising a shield portion built in the wiring board, wherein
the shield portion includes a feedthrough ground via conductor arranged to surround the second electronic component when viewed in plan in the thickness direction defined for the core board.

5. The radio frequency module of claim 1, further comprising a third electronic component built in the wiring board, wherein
the core board further has a second through hole different from a first through hole serving as the through hole, and
the third electronic component is disposed inside the second through hole of the core board and has a smaller area than the second electronic component when viewed in plan in the thickness direction defined for the core board.

6. The radio frequency module of claim 5, further comprising a fourth electronic component disposed on the wiring board, wherein
the fourth electronic component is an IC chip, and
the third electronic component is a chip capacitor and is a constituent component of a matching circuit connected to the fourth electronic component.

7. The radio frequency module of claim 6, wherein
the third electronic component comprises a plurality of third electronic components, and the plurality of third-electronic components comprises a transverse mounted chip capacitor and a longitudinally mounted chip capacitor.

8. The radio frequency module of claim 1, further comprising a first heat dissipating portion overlapping with the second electronic component when viewed in plan in the thickness direction defined for the core board.

9. The radio frequency module of claim 8, wherein
the first heat dissipating portion is separated from the second electronic component in the thickness direction defined for the core board.

10. The radio frequency module of claim 8, wherein
the first heat dissipating portion is in contact with the second electronic component in the thickness direction defined for the core board.

11. The radio frequency module of claim 9, further comprising:
a shield layer; and
a second heat dissipating portion different from the first heat dissipating portion, wherein
the second heat dissipating portion overlaps with the second electronic component when viewed in plan in the thickness direction defined for the core board and is in contact with the shield layer.

12. The radio frequency module of claim 1, further comprising another electronic component disposed on the second buildup layer, wherein
the second electronic component overlaps with the other electronic component disposed on the second buildup layer in the thickness direction defined for the core board.

13. The radio frequency module of claim 2, wherein
the second electronic component is an IC chip, and
the first electronic component is a constituent component of a matching circuit connected to the second electronic component.

14. The radio frequency module of claim 2, further comprising a third electronic component built in the wiring board, wherein
the core board further has a second through hole different from a first through hole serving as the through hole, and
the third electronic component is disposed inside the second through hole of the core board and has a smaller area than the second electronic component when viewed in plan in the thickness direction defined for the core board.

15. The radio frequency module of claim 3, further comprising a third electronic component built in the wiring board, wherein
the core board further has a second through hole different from a first through hole serving as the through hole, and
the third electronic component is disposed inside the second through hole of the core board and has a smaller area than the second electronic component when viewed in plan in the thickness direction defined for the core board.

16. The radio frequency module of claim 4, further comprising a third electronic component built in the wiring board, wherein
the core board further has a second through hole different from a first through hole serving as the through hole, and
the third electronic component is disposed inside the second through hole of the core board and has a smaller area than the second electronic component when viewed in plan in the thickness direction defined for the core board.

17. The radio frequency module of claim 2, further comprising a first heat dissipating portion overlapping with the second electronic component when viewed in plan in the thickness direction defined for the core board.

18. The radio frequency module of claim 3, further comprising a first heat dissipating portion overlapping with the second electronic component when viewed in plan in the thickness direction defined for the core board.

19. The radio frequency module of claim 4, further comprising a first heat dissipating portion overlapping with the second electronic component when viewed in plan in the thickness direction defined for the core board.

20. The radio frequency module of claim 5, further comprising a first heat dissipating portion overlapping with the second electronic component when viewed in plan in the thickness direction defined for the core board.
